(19) United States
(12) Patent Application Publication
(10) Pub. No.: US 2007/0226993 A1
(43) Pub. Date: Oct. 4, 2007

(54) Apparatus for adhering electronic device and a method for adhering electronic device

(75) Inventors: Liang-Jung Liu, Taipei Hsien (TW); Chih-Ching Chen, Taipei Hsien (TW)

Correspondence Address: VENABLE LLP, P.O. BOX 34385, WASHINGTON, DC, 20043-9998, US

(73) Assignee: CHICONY ELECTRONICS CO., LTD, Taipei (TW)

(21) Appl. No.: 11/730,099

(22) Filed: Mar. 29, 2007

(30) Foreign Application Priority Data
Apr. 4, 2006 (TW) 095111914

(51) Int. Cl. H05K 13/04

(52) U.S. Cl. 29/729; 29/739; 29/832; 156/256; 156/277

(57) ABSTRACT

The present invention provides an apparatus for adhering electronic devices comprising an electronic device, an adhesive, and a circuit board. Because the conventional circuit board includes air bubbles, these air bubbles are heated to the expansion state so as to forming the illness structure with holes. The circuit board of the present invention has an improved structure to improve the speed of filling and forming shape of the adhesive disposed at the bottom of the electronic device, so that when the electronic device is placed on the circuit board with the edges thereof coated with the adhesive, it can be adhered on the circuit board quickly while it can render the air in the interlayer between the electronic device and the circuit board exhausted through the hole. In addition, the present invention provides a method for adhering electronic devices, in order for the electronic device to be adhered on the circuit board quickly.

### BACKGROUND OF THE INVENTION

1. Field of the Invention

The present invention relates an apparatus for adhering electronic devices. More particularly, the present invention relates a circuit board having an improved structure to improve the speed of filling and forming shape of the adhesive disposed at the bottom of the electronic device.

2. Descriptions of the Related Art

The modern electronic industry has been in vigorous development continuously, with a great variety of electronic products making more comfortable and convenient lives for the people. By far, the speed of filling and forming shape of the adhesive disposed at the bottom of the electronic device in current manufacturing processes for electronic products are critical issues to dealt with.

In the past, to adhere an electronic device on a circuit board, the electronic device is soldered onto the circuit board and then coated with an adhesive at a plurality of peripheral edges thereof so that an effect of adhesion can be achieved by capillarity of the adhesive colloid, which renders the colloid expanding from the edges of the electronic device to the inside of the adhesive faces of the electronic device. As shown in FIG. 2A, in case that each of the edges has the adhesive applied thereon for a closed coating, bubbles 40 as shown in FIG. 2B may be enveloped within the seams and cannot be exhausted, and explosions 41 of the colloid may occur in the heating and curing processes, as shown in FIG. 2D. Also, the product, when being heated, may have electronic faults that are formed due to an opening 42 between adhesive layers, which is caused by the bubble expansion, as shown in FIG. 2C. Refer to FIG. 3A and FIG. 3B, if only a portion of the edges is coated, the flow rate will change, depending on the characteristic of the adhesive, while the total adhesion time will increase, which requires an improvement.

### SUMMARY OF THE INVENTION

The prior art has the disadvantage that the time for coating an adhesive is spent greatly or the produced appearance and the electronic behavior fault abnormally. In view of this, the apparatus for adhering electronic devices and the method for adhering the electronic devices according to the present invention may effectively resolve the above-mentioned problems, i.e., greatly spent time or abnormal faults of the produced appearance and the electronic behavior. The inventive apparatus has an electronic device, an adhesive and a circuit board. A region is disposed at a defined position of the circuit board and at least one hole is disposed in the region.

The electronic device has the bottom thereof soldered on the circuit board, with the adhesive applied to the peripheral edges thereof, wherein when the adhesive is present between the electronic device and the circuit board, the air in the interlayer between the electronic device and the circuit board can be exhausted through this hole so as for a siphonage to be proceeded. The adhesion has an effect that the adhesion time is shorten and the appearance and the electric condition are both good.

Preferably, when the edges of the electronic device come to be in closed combination with the circuit board by the adhesive, the air in the interlayer between the electronic device and the circuit board can be exhausted through this hole so as for a siphonage to be proceeded, wherein more than two edges of the electronic device are closed by the adhesive.

Preferably, when the edges of the electronic device come to be in closed combination with the circuit board by the adhesive, the air in the interlayer between the electronic device and the circuit board can be exhausted through this hole so as for a siphonage to be proceeded, wherein each edge of the electronic device is closed by the adhesive.

Preferably, when the edges of the electronic device come to be in closed combination with the circuit board by the adhesive, the air in the interlayer between the electronic device and the circuit board can be exhausted through this hole so as for a siphonage to be proceeded, wherein the hole is sucked with an externally applied force for speeding up exhausting the air therein.

### BRIEF DESCRIPTION OF THE DRAWINGS

FIG. 1A is a top view of the apparatus for adhering electronic device of the present invention.

FIG. 1B is a cross sectional view along line A-A in FIG. 1A.

FIG. 2A is a top view of a conventional circuit board on which an electronic device is adhered.

FIG. 2B is a cross sectional view along line B-B in FIG. 2A.

FIG. 2C is a cross sectional view of another aspect along line B-B in FIG. 2A.

FIG. 2D is a cross sectional view of yet another aspect along line B-B in FIG. 2A.

FIG. 3A is a top view of that, conventionally, an electronic device coated a portion of the edges thereof.

FIG. 3B is a top view of that, conventionally, an electronic device coated a portion of the edges thereof for another aspect.

### DETAILED DESCRIPTION OF THE INVENTION

The present invention will be described fully with reference to the accompanying drawings provided with preferred embodiments of the invention, but it will be understood, prior to this description, that modifications of the invention described herein may be made by those skilled in the art while the functions of the invention can be achieved. Therefore, it will be understood that the following description is a general disclosure to those skilled in the art and the content thereof is not intended to limit the present invention.

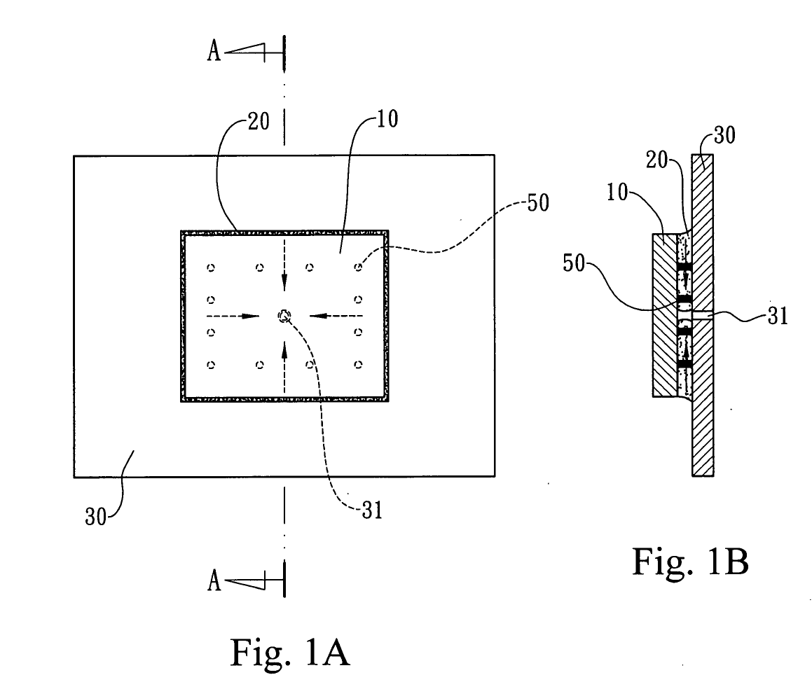

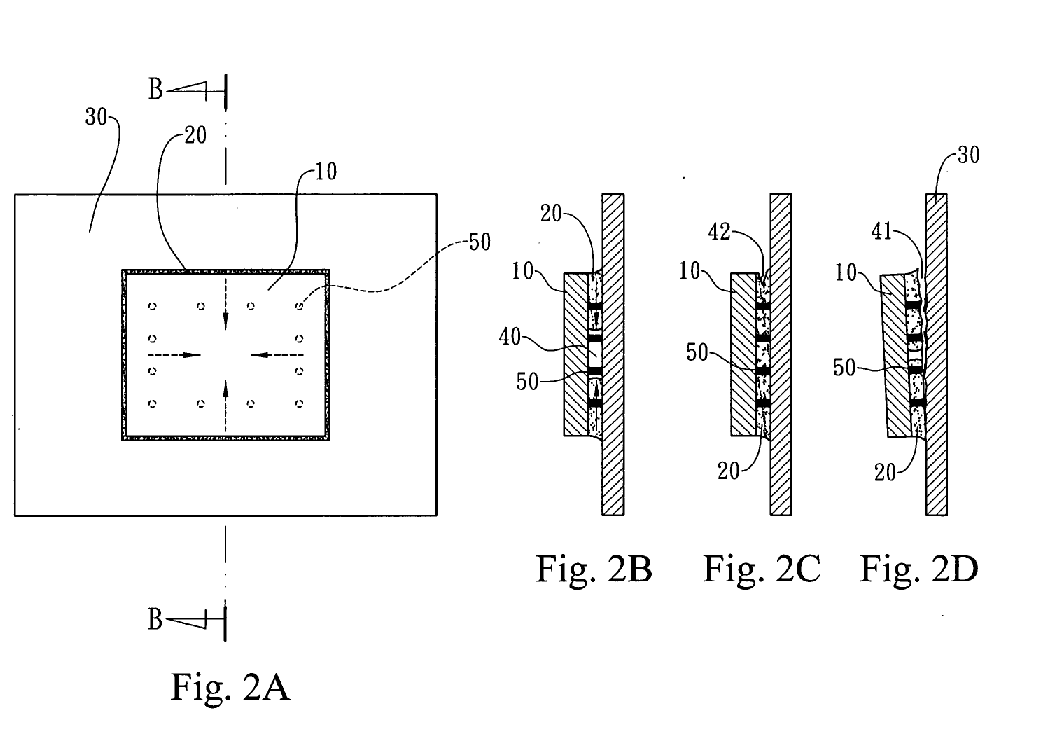

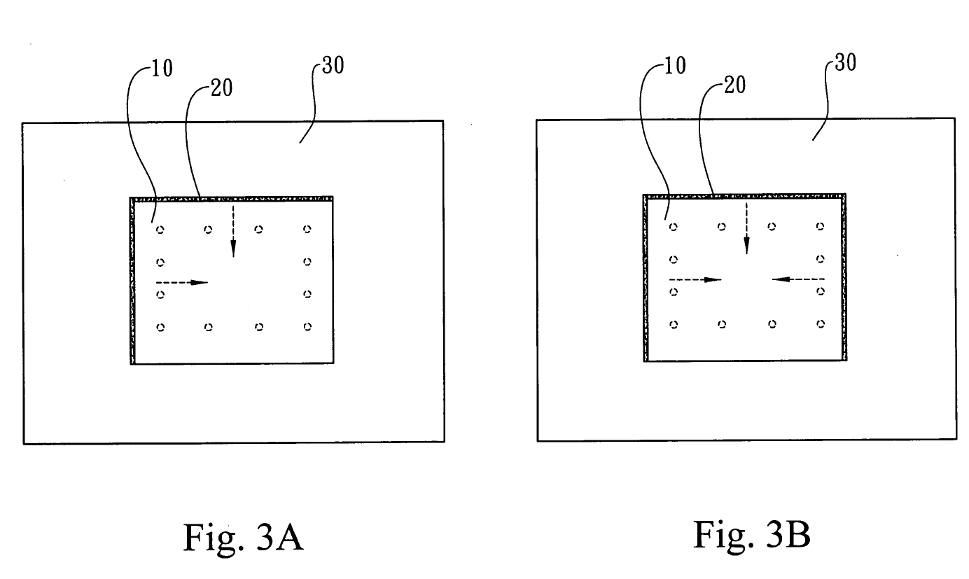

Refer to FIGS. 1A and 1B, which show a top view of the apparatus for adhering electronic devices of the present invention and a sectional view along line A-A in FIG. 1A, respectively. In a preferred embodiment, the apparatus of the present invention has an electronic device 10; an adhesive 20, providing the adhesion function for the electronic device 10 with a circuit board 30; and a circuit board 30, having a suitably defined region and at least one hole 31 disposed in the region, wherein the electronic device 10 is soldered in the region of the circuit board 30 with a solder 50 and the hole 31 enables the air in the interlayer between the electronic device 10 and the circuit board 30 to be exhausted therethrough when the edges of the electronic device 10 come to be in combination with the circuit board 30 by the adhesive 20 so as for a siphonage to be proceeded.

The electronic device 10, being soldered on the circuit board 30 with the solder 50, has a plurality of edges coated with the adhesive 20, as shown in FIG. 1A for this embodiment that has all the four edges coated with the adhesive 20.

The adhesive 20 provides the adhesion function for the electronic device 10 with the circuit board 30, so that when the edges of the electronic device 10 come to be in closed combination with the circuit board 30 by the adhesive 20, the air in the interlayer between the electronic device 10 and the circuit board 30 can be exhausted through the hole 31 so as for a siphonage to be proceeded, wherein more than two edges of the electronic device 10 are coated and closed by the adhesive 20.

When the edges of the electronic device 10 come to be in closed combination with the circuit board 30 by the adhesive 20, the air in the interlayer between the electronic device 10 and the circuit board 30 can be exhausted through the hole 31 so as for a siphonage to be proceeded, wherein each edge of the electronic device 10 is coated and closed by the adhesive 20.

When the edges of the electronic device 10 come to be in closed combination with the circuit board 30 by the adhesive 20, the air in the interlayer between the electronic device 10 and the circuit board 30 can be exhausted through the hole 31 so as for a siphonage to be proceeded, wherein the hole 31 is sucked with an externally applied force for speeding up exhausting the air therein.

In the preferred embodiments described above, the method for adhering electronic devices according the present invention comprises steps: defining a region on a circuit board 30 and opening at least one hole 31 in the region; soldering an electronic device 10 on the circuit board 30; and coating the edges of the electronic device 10 with an adhesive 20 so as for the adhesive 20 to permeate the gap between the electronic device 10 and the circuit board 30, wherein the hole 31 may be sucked with an externally applied force for speeding up exhausting the air therein. With the preferred embodiments of the present invention described in details, those skilled in the art should understand clearly that various changes and modifications may be made without departing the scope and spirit of the appended claims and the present invention is not limited to the implementation of the embodiments exemplified in the specification.

What is claimed is:

1. An apparatus for adhering electronic devices, comprising:
an electronic device;
an adhesive; and
a circuit board;
wherein said electronic device is soldered on the circuit board, and said adhesive applied to the edges of said electronic device so as for said adhesive to permeate the gap between said electronic device and said circuit board, and at least one hole is disposed on a adhesion region of said circuit board corresponding to said electronic device.

2. The apparatus for adhering electronic devices of claim 1, wherein more than two edges of said electronic device are coated with said adhesive.

3. The apparatus for adhering electronic devices of claim 1, wherein each edge of said electronic device is coated with the adhesive.

4. The apparatus for adhering electronic devices of claim 1, wherein said hole is sucked with an externally applied force for speeding up exhausting the air therein.

5. A method for adhering electronic devices, comprising:
defining a region on a circuit board and at least one hole disposed at said region;
soldering an electronic device on said circuit board; and
coating the edges of said electronic device with an adhesive so as for said adhesive to permeate a gap between said electronic device and said circuit board.

6. The method for adhering electronic devices of claim 5, wherein more than two edges of said electronic device are coated with said adhesive.

7. The method for adhering electronic devices of claim 5, wherein each edge of said electronic device is coated with said adhesive.

8. The method for adhering electronic devices of claim 5, wherein said hole is sucked with an externally applied force for speeding up exhausting the air therein.
